(19) United States
(12) Patent Application Publication
(10) Pub. No.: US 2007/0113886 A1
(43) Pub. Date: May 24, 2007

(54) PHOTOELECTRIC CONVERSION DEVICE

(75) Inventors: Tatsuya Arao, Ebina-shi, Kanagawa-ken (JP); Naoto Kusumoto, Atsugi-shi, Kanagawa-ken (JP); Daiki Yamada, Techigi (JP); Hidekazu Takahashi, Tochigi (JP); Kazuo NISHI, Atsugi-shi, Kanagawa-ken (JP); Yuusuke Sugawara, Atsugi-shi, Kanagawa-ken (JP); Hironobu Takahashi, Atsugi-shi, Kanagawa-ken (JP); Shuji Fukai, Atsugi-shi, Kanagawa-ken (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/559,477

(22) Filed: Nov. 14, 2006

(30) Foreign Application Priority Data
Nov. 18, 2005 (JP) 2005-334854

(51) Int. Cl. H01L 31/00

(52) U.S. Cl. 136/256

(57) ABSTRACT

A photoelectric conversion device provided with a photoelectric conversion layer between a first electrode and a second electrode is formed. The first electrode is partially in contact with the photoelectric conversion layer, and a cross-sectional shape of the first electrode in the contact portion is a taper shape. In this case, part of a first semiconductor layer with one conductivity type is in contact with the first electrode. A planer shape in an edge portion of the first electrode is preferably nonangular, that is, a shape in which edges are planed or a curved shape. By such a structure, concentration of an electric field and concentration of a stress can be suppressed, whereby characteristic deterioration of the photoelectric conversion device can be reduced.

### TECHNICAL FIELD

The present invention relates to a photoelectric conversion device that outputs an electric signal depending on intensity of light that is received.

### BACKGROUND ART

As a photoelectric conversion device used for detecting an electromagnetic wave, one having sensitivity from UV light to infrared light is also called a light sensor in general. Above all, one having sensitivity in a visible light ray region with a wave length of 400 to 700 nm is called a visible light sensor, which is variously used for equipment that needs illuminance adjustment or on-off control depending on living environment.

A light sensor device is known, in which, with the use of an amorphous silicon photodiode that is used as such a light sensor that has sensitivity in a visible light ray region, the amorphous silicon photodiode and an amplifier including a thin film transistor are formed in an integrated manner (for example, refer to Patent Document 1: Japanese Published Patent Application No. 2005-129909).

### DISCLOSURE OF INVENTION

A light sensor is mounted on a cellular phone and the like to be used for adjusting amount of light of a backlight in a liquid crystal display. A light sensor has a diode type structure provided with a photoelectric conversion characteristic. In order to extract light that is received as a current with favorable sensitivity, a reverse bias is applied to the light sensor by being connected to an electrode. Further, in order to add a process to an output current, the light sensor is driven by being connected to an amplifier circuit, a signal processing circuit, or the like, which is formed by a transistor.

However, a photoelectric conversion device that is formed by stacking a thin film, such as an amorphous silicon photodiode or a thin film transistor, has a problem that an operation characteristic is deteriorated by adding a stress due to electric or physical operation.

In order to solve such a problem, it is an object of the present invention to improve reliability of a photoelectric conversion device.

According to the present invention, a connecting portion of an electrode and a photoelectric conversion layer is improved to prevent concentration of an electric filed in the connecting portion, thereby suppressing deterioration of a characteristic.

One aspect of the present invention is a photoelectric conversion device including a photoelectric conversion layer having a first semiconductor layer with one conductivity type, a second semiconductor layer, and a third semiconductor layer with a conductivity type opposite to one conductivity type; a first electrode in contact with the first semiconductor layer; and a second electrode in contact with the third semiconductor layer. In the photoelectric conversion device, a cross-sectional shape of an edge portion of the first electrode in a portion being contacted with the first semiconductor layer is a taper shape.

In the present invention, a taper angle of an edge portion in a cross-section of the first electrode is preferably equal to or less than 80 degrees. In addition, an angle of a vertex of a cross-section of the first electrode in a portion being contacted with the first semiconductor layer is set to be larger than 90 degrees.

In such a manner, by making a cross-sectional structure of the first electrode have a taper shape, step coverage of a photoelectric conversion layer can be improved, and an electric or physical stress can be relieved.

Further, by forming a planer structure of the first electrode so as not to have an angular portion, step coverage of a photoelectric conversion layer can be improved, and an electric or physical stress can be relieved.

Another aspect of the present invention is a photoelectric conversion device provided with a photoelectric conversion layer between a first electrode and a second electrode. The photoelectric conversion device includes a photoelectric conversion layer having a first semiconductor layer with one conductivity type, a second semiconductor layer, and a third semiconductor layer with a conductivity type opposite to one conductivity type over a substrate; a first electrode in contact with the first semiconductor layer; a second electrode in contact with the third semiconductor layer; and a protective film in contact with the first semiconductor layer and the first electrode. In the photoelectric conversion device, a cross-sectional shape of an edge portion of the protective film in a portion being contacted with the first semiconductor layer is a taper shape.

In the present invention, a cross-sectional shape of an edge portion of the first electrode in a portion being contacted with the protective film may be a taper shape. In addition, at this time, a taper angle of a cross-section in the edge portion of the first electrode is preferably equal to or less than 80 degrees.

In the present invention, a taper angle of a cross-section in an edge portion of the protective film is preferably equal to or less than 80 degrees. In addition, an angle of a vertex of a cross-section of the protective film in a portion being contacted with the first semiconductor layer is set to be larger than 90 degrees.

In such a manner, by making a cross-sectional structure of the protective film have a taper shape, step coverage of a photoelectric conversion layer can be improved, and an electric or physical stress can be relieved.

Further, by forming a planner structure of the protective film so as not to have an angular portion, step coverage of a photoelectric conversion layer can be improved, and an electric or physical stress can be relieved.

In the present invention, the protective film is preferably an insulating material or a material having higher resistance than that of the first semiconductor layer. In addition, the protective film is preferably a light transmitting resin that transmits light of a visible light band. Moreover, the protective film is preferably a photosensitive material.

In the present invention, the protective film may have a function of selectively transmitting light of a specific wavelength band (a specific color), so-called of a color filter.

In the above structure of the invention, the first electrode can be connected to a transistor. A thin film transistor is preferable as the transistor.

In order to hold the electrode, the photoelectric conversion layer, and the transistor, a glass substrate, a plastic substrate, or the like can be applied. The substrate may have flexibility.

In accordance with the present invention, concentration of an electric field and concentration of a stress can be suppressed in a connecting portion of a photoelectric conversion layer and an electrode, and then, characteristic deterioration can be reduced. Therefore, reliability of a photoelectric conversion device can be improved.

### BRIEF DESCRIPTION OF DRAWINGS

FIG. 1 is a diagram for showing a circuit configuration relating to a photoelectric conversion device of the present invention.

FIGS. 2A and 2B are cross-sectional views of a photoelectric conversion device of the present invention.

FIGS. 3A and 3B are a cross-sectional view and a planer view of a photoelectric conversion device of the present invention.

FIGS. 4A to 4D are cross-sectional views for showing a manufacturing step of a photoelectric conversion device of the present invention.

FIGS. 5A to 5C are cross-sectional views for showing a manufacturing step of a photoelectric conversion device of the present invention.

FIGS. 6A and 6B are cross-sectional views of a photoelectric conversion device of the present invention.

FIG. 7 is a view for showing a device on which a photoelectric conversion device of the present invention is mounted.

FIGS. 8A and 8B are views for showing a device on which a photoelectric conversion device of the present invention is mounted.

FIGS. 9A and 9B are views for showing a device on which a photoelectric conversion device of the present invention is mounted.

FIG. 10 is a view for showing a device on which a photoelectric conversion device of the present invention is mounted.

FIGS. 11A and 11B are views for showing a device on which a photoelectric conversion device of the present invention is mounted.

### BEST MODE FOR CARRYING OUT THE INVENTION

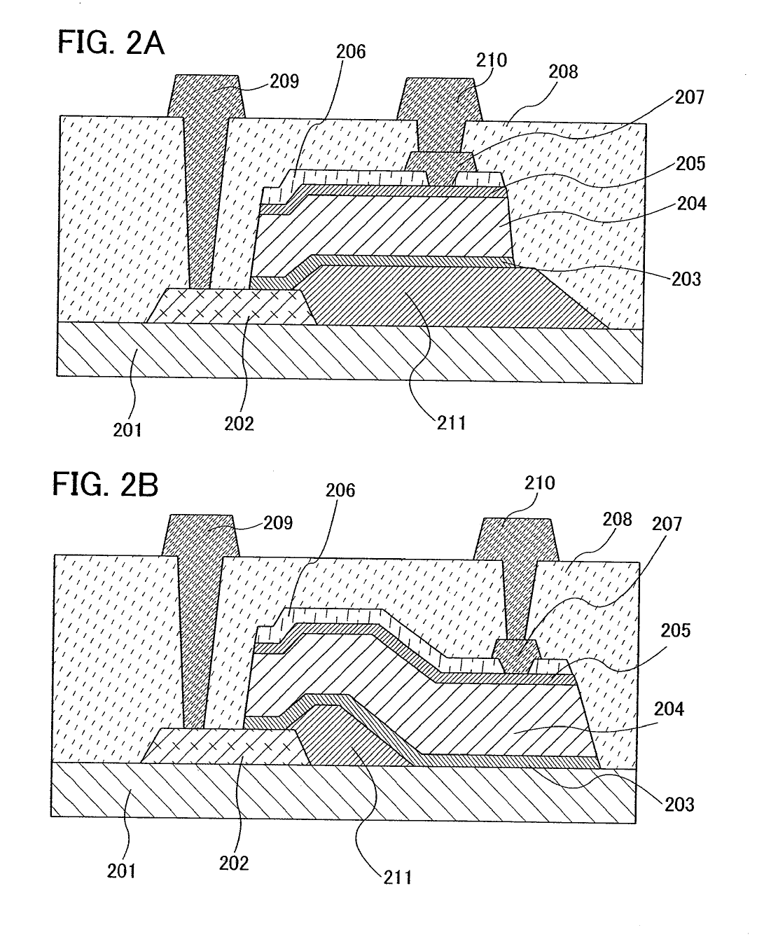

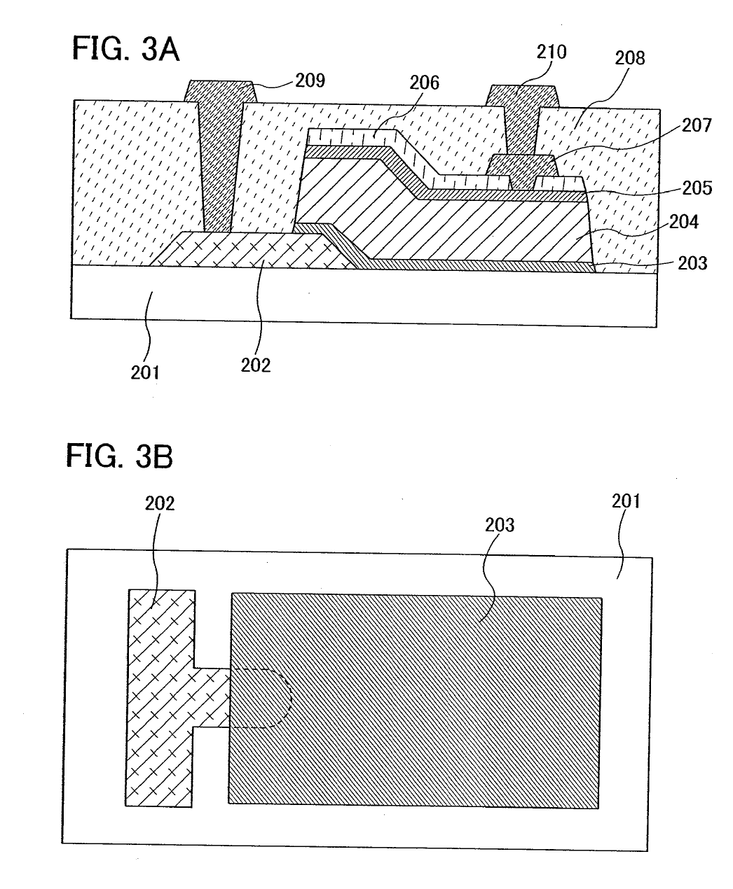

Embodiment Mode of the present invention will be explained with reference to FIGS. 2A and 2B, and FIGS. 3A and 3B. FIG. 3B is a view seen from a substrate side of FIG. 3A.

As a substrate 201, a glass substrate is used. Alternatively, a flexible substrate may be used. When light to a photoelectric conversion layer enters from a substrate 201 side, the substrate 201 desirably has high transmittance. Further, when the substrate 201 has selectivity of a light transmitting wavelength with respect to a wavelength in a range of visible light, a light sensor can have sensitivity in a specific wavelength range.

As an electrode 202, titanium (Ti) is used. This electrode may have conductivity and be formed of a single-layer film or stacked-layer film. For an uppermost surface layer of the electrode, a material that does not change a photoelectric conversion characteristic by transforming the photoelectric conversion layer by heat treatment is desirably used.

As a protective film 211, polyimide is used. This protective film is used in order to reduce a coverage defect of the photoelectric conversion layer in an edge portion of the electrode 202 by covering the edge portion of the electrode 202 and not to cause concentration of an electric field in the edge portion; therefore, the protective film is not limited to polyimide. This protective film can achieve the purpose even if it is not an insulating film, and the protective film may have conductivity. However, static electricity resistance deteriorates in a case of excessively high conductivity. Therefore, the protective film has high resistance desirably. In a case of using an organic resin such as polyimide, the protective film can be easily formed only by coating, light exposure, development, and baking by using a photosensitive material, and a taper becomes moderate; therefore, coverage of a film manufactured in a subsequent step can be improved. When light enters from the substrate 201 side, a protective film having high light transmittance is desirably used.

As for the photoelectric conversion layer, a p-type semiconductor layer 203, an i-type semiconductor layer 204, and an n-type semiconductor layer 205 are used. In this mode, a silicon film is used for a semiconductor film. The silicon film may be amorphous or semiamorphous. In the present specification, the i-type semiconductor layer indicates a semiconductor layer in which an impurity imparting p-type or n-type contained in the semiconductor layer has a concentration of equal to or less than 1×10²⁰ cm⁻³, oxygen and nitrogen have a concentration of equal to or less than 5×10¹⁹ cm⁻¹, and photoconductivity of equal to or more than 1000 times with respect to dark conductivity is included. Further, boron (B) of 10 to 1000 ppm may be added to the i-type semiconductor layer.

In order to improve reliability for a light resistance property, a p-type semiconductor layer is desirably used on light entry side. Therefore, in a case where light enters from a direction opposite to the substrate 201, reference numeral 205 can denotes a p-type semiconductor layer, and reference numeral 203 can denotes an n-type semiconductor layer.

As for insulating films 206 and 208, an epoxy resin is used. These insulating films may each have an insulating property, and accordingly, they are not limited to an epoxy resin. When light enters from a direction opposite to the substrate 201, an insulating film having high light transmittance is desirably used.

As for electrodes 207, 209, and 210, nickel (Ni) is used. These electrodes may each have conductivity. In a case of forming the electrodes by screen printing, a conductive paste can be used. Alternatively, an ink jet method can be used. In order to improve wettability with respect to solder in mounting, the electrode 210 may have a stacked structure by forming copper (Cu) over the surface of the electrode.

Here, the insulating film 206 and the electrode 207 are used as a mask in forming the photoelectric conversion layer.

As a formation of the protective film 211, there are two cases: a case where the protective film 211 is formed in entirely contact with one surface of the p-type semiconductor layer 203 in accordance with the shape as shown in FIG. 2A; and another case where the protective film 211 is formed only on the periphery of an edge portion of the electrode 202 as shown in FIG. 2B. In a structure of FIG. 2A, the p-type semiconductor layer 203 is in contact with the protective film 211 that is newly formed; therefore, a stable characteristic can be obtained regardless of a state of a base film. Alternatively, in a structure of FIG. 2B, light reaches the photoelectric conversion layer without passing through the protective film 211; therefore, light use efficiency is high.

In addition, although not illustrated, an entire surface of the electrode 202 other than a portion that is electrically connected to an upper structure can be covered with the protective film 211. However, when a resin material is used for the protective film, intensity may be lowered. Accordingly, an inorganic material is desirably used in the case of covering the entire surface.

As shown in FIG. 3A, in a case where the protective film 211 is not used, an edge portion of the electrode 202 may have a taper shape. By making the edge portion have a taper shape, coverage of the electrode 202 and the photoelectric conversion layer can be improved, and reliability can be improved.

It is to be noted that any structure can prevent concentration of an electric field by removing an angle from a planner shape in a portion where the electrode 202 and the photoelectric conversion layer are in contact with each other as shown in FIG. 3B, and coverage instability of the photoelectric conversion layer due to an angle portion can be removed. Accordingly, concentration of an electric filed and concentration of a stress can be suppressed in a connecting portion of the photoelectric conversion layer and the electrode, and then, characteristic deterioration can be reduced to improve reliability of the photoelectric conversion device.

### Embodiment 1

In this embodiment, one example of a photoelectric conversion device using a thin film transistor and a photodiode will be explained.

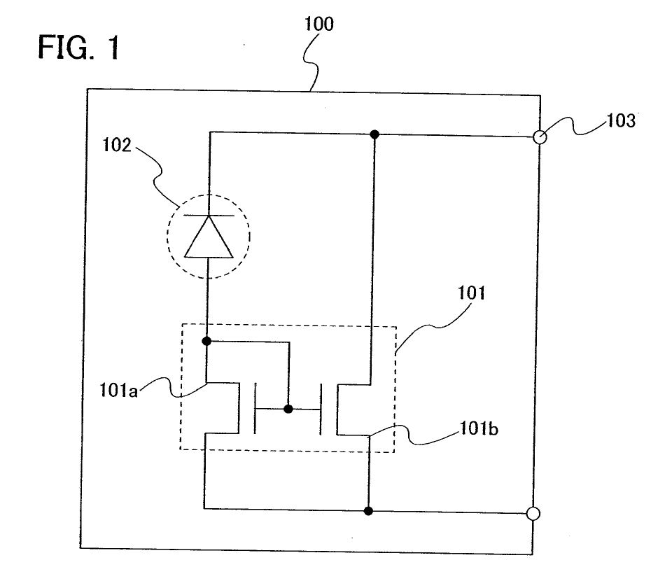

In a photoelectric conversion device shown in this embodiment, a photodiode and an amplifier circuit that is formed by a thin film transistor are formed in an integrated manner over a same substrate. FIG. 1 shows one example of a configuration as a circuit diagram. This photoelectric conversion device 100 is provided with an amplifier circuit 101 that amplifies output of a photodiode 102. Various circuit configurations can be applied to the amplifier circuit 101. In this embodiment, a current mirror circuit is formed by a thin film transistor 101a and a thin film transistor 101b. Source terminals of the thin film transistors 101a and 101b are each connected to an external power supply GND. A drain terminal of the thin film transistor 101b is connected to an output terminal 103. The photodiode 102 may be provided with a pn junction, a pin junction, or a function equal to the junction. An anode (a p layer side) of the photodiode 102 is connected to a drain terminal of the thin film transistor 101a, and a cathode (an n layer side) thereof is connected to the output terminal 103.

When the photodiode 102 is irradiated with light, a photoelectric current flows from the cathode (the n layer side) to the anode (the p layer side). Accordingly, a current flows in the thin film transistor 101a of the amplifier circuit 101, and a voltage necessary for flow of a current is generated in a gate. In a case where gate length L and channel width W of the thin film transistor 101b are equal to those of the thin film transistor 101a, gate voltages of the thin film transistors 101a and 101b are equal to each other in a saturation region; therefore, a current with the same value flows. In order to obtain desired amplification, the thin film transistor 101b may be connected in parallel. In this case, a current that is amplified in proportion to the number (n pieces) of the transistor connected in parallel can be obtained.

It is to be noted that FIG. 1 shows a case where an n-channel thin film transistor is used; however, when a p-channel thin film transistor is used, a photoelectric conversion device having the similar function can be formed.

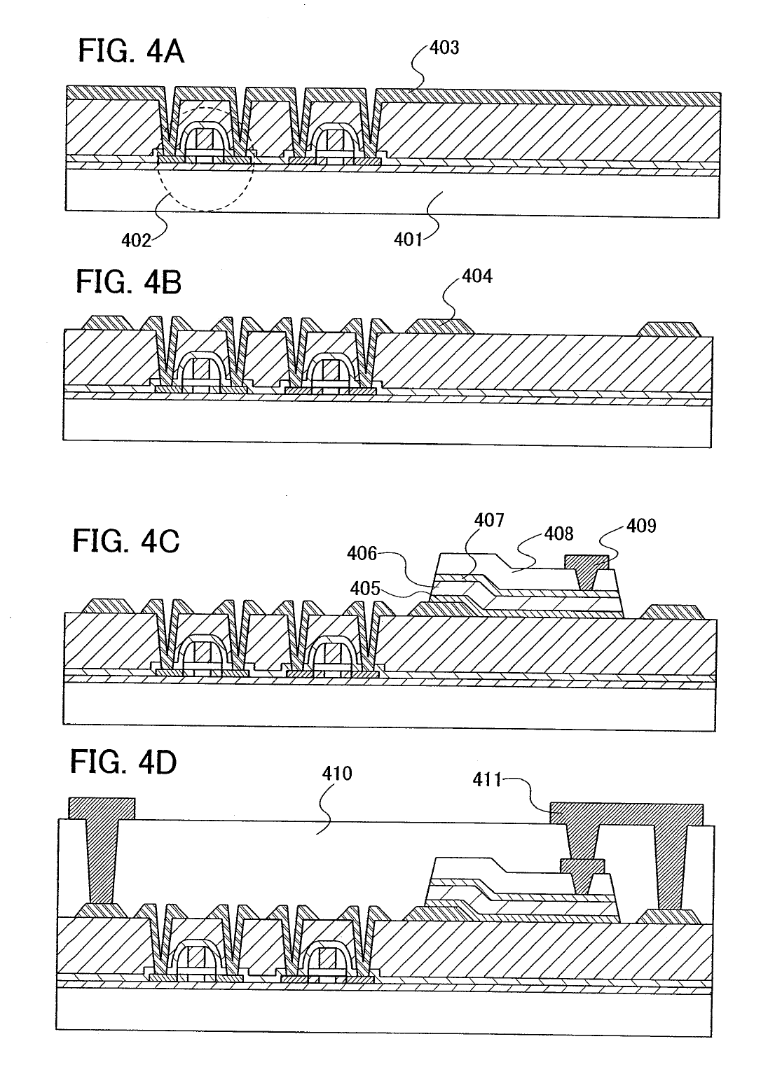

Next, a method for manufacturing a photoelectric conversion device provided with a thin film transistor and a photodiode will be explained with reference to drawings. A thin film transistor 402 is formed over a glass substrate 401. An electrode 403 connected to the thin film transistor 402 is formed. In this embodiment, titanium (Ti) with a thickness of 400 nm is formed as the electrode 403 by a sputtering method (refer to FIG. 4A). Although the electrode 403 may be made of a conductive material, a conductive metal film that is not easily reacted with a photoelectric conversion layer (typically, amorphous silicon) formed afterwards to be an alloy is desirably used.

Subsequently, etching is performed so that edge portions of the electrode 403 have a taper shape, thereby forming an electrode 404. The electrode 404 is formed to have a taper angle of equal to or less than 80 degrees, desirably, equal to or less than 45 degrees. Accordingly, coverage of the photoelectric conversion layer formed afterwards becomes favorable, and then, reliability can be improved (refer to FIG. 4B). A portion that is in contact with the photoelectric conversion layer formed afterwards is formed so that the electrode 404 has a planer shape, that is an angle of a vertex of the electrode 404 in a cross-section of the electrode 404 has larger than 90 degrees, desirably, further an nonangular shape.

Then, a p-type semiconductor film is formed. In this embodiment, as the p-type semiconductor film, for example, a p-type amorphous semiconductor film is formed. As the p-type amorphous semiconductor film, an amorphous silicon film containing an impurity element belonging to Group 13 of the periodic table, for example, boron (B) is formed by a plasma CVD method.

After forming the p-type semiconductor film, an i-type semiconductor film (also referred to as an intrinsic semiconductor film) that contains no impurity imparting conductivity and an n-type semiconductor film are sequentially formed. In this embodiment, the p-type semiconductor film with a film thickness of 10 to 50 nm, the i-type semiconductor film with a film thickness of 200 to 1000 nm, and the n-type semiconductor film with a film thickness of 20 to 200 nm are formed.

As the i-type semiconductor film, for example, an amorphous silicon film may be formed by a plasma CVD method. Further, as the n-type semiconductor film, an amorphous silicon film containing an impurity element belonging to Group 15 of the periodic table, for example, phosphorus (P) may be formed. Alternatively, as the n-type semiconductor film, an impurity element belonging to Group 15 of the periodic table may be introduced after forming an amorphous silicon film.

It is to be noted that the p-type semiconductor film, the i-type semiconductor film, and the n-type semiconductor film may be stacked in an reverse order, that is, the n-type semiconductor film, the i-type semiconductor film, and the p-type semiconductor film may be stacked in this order.

Further, as the p-type semiconductor film, the i-type semiconductor film, and the n-type semiconductor film, a semiamorphous semiconductor film may be used in addition to an amorphous semiconductor film.

It is to be noted that a semiamorphous semiconductor film is a film containing a semiconductor having an intermediate structure between an amorphous semiconductor and a semiconductor (including a single crystal and a poly crystal) film having a crystalline structure. This semiamorphous semiconductor film is a semiconductor film having a third state that is stable in terms of free energy and is a crystalline substance having a short-range order and lattice distortion. A crystal grain thereof can be dispersed in the non-single crystal semiconductor film by setting a grain size thereof to be 0.5 to 20 nm. Raman spectrum thereof is shifted toward lower wave number than 520 cm⁻¹. The diffraction peaks of (111) and (220), which are considered to be derived from a Si crystal lattice, are observed in the semiamorphous semiconductor film by X-ray diffraction. The semiamorphous semiconductor film contains hydrogen or halogen of at least equal to or more than 1 atomic % as a material for terminating a dangling bond. In the present specification, such a semiconductor film is referred to as a semiamorphous semiconductor (SAS) film for the sake of convenience. The lattice distortion is further extended by adding a rare gas element such as helium, argon, krypton, and neon so that favorable a semiamorphous semiconductor film with improved stability can be obtained. It is to be noted that a microcrystal semiconductor film is also included in the semiamorphous semiconductor film.

An SAS film can be formed by a plasma CVD method. A typical material gas is SiH₄. Alternatively, Si₂H₆, SiH₂Cl₂, SiHCl₃, SiCl₄, SiF₄, or the like can be used. Further, an SAS film can be easily formed by using the material gas diluted with hydrogen or gas to hydrogen which one or more of rare gas elements selected from helium, argon, krypton, and neon are added. The material gas such as SiH₄ is preferably diluted with a dilution ratio of 2 to 1000 fold. In addition, a carbide gas such as CH₄ or C₂H₆; a germanide gas such as GeH₄ and GeF₄; F₂; and the like may be mixed into the material gas such as SiH₄ to adjust the width of an energy band at 1.5 to 2.4 eV or 0.9 to 1.1 eV.

Next, an insulating film 408 and an electrode 409 are formed by a screen printing method or by an ink jet method. Alternatively, the insulating film 408 and the electrode 409 may be formed over an entire surface to form a desired shape by photolithography. In this embodiment, an epoxy resin is used for the insulating film 408, and nickel (Ni) is used for the electrode 409. When nickel (Ni) is formed by a screen printing method, a conductive paste containing nickel is used.

Subsequently, the p-type semiconductor film, the i-type semiconductor film, and the n-type semiconductor film are etched using the insulating film 408 and the electrode 409 as a mask to form a p-type semiconductor layer 405, an i-type semiconductor layer 406, and an n-type semiconductor layer 407 (refer to FIG. 4C). In this etching, there is a case where a film of the electrode 404 is etched by over etching. In such a case, a problem such as reduction of conductivity is caused. Therefore, etching selectivity between the p-type semiconductor film, the i-type semiconductor film, and the n-type semiconductor film and the electrode 404 is desirably set to be large.

Then, an insulating film 410 and an electrode 411 are formed by a screen printing method. In this embodiment, an epoxy resin is used for the insulating film 410, and the electrode 411 has a stacked structure of nickel (Ni) and copper (Cu) for improvement in wettability to solder and improvement in intensity in mounting (refer to FIG. 4D).

In a case where light enters from a glass substrate 401 side, light is made to interfere by adjusting a film thickness of a plurality of insulating films, each of which a refraction index is different, forming the thin film transistor 402, and wavelength distribution of light that enters in a photoelectric conversion layer can be controlled. By adjusting the wavelength distribution of light so as to be close to human visibility as much as possible, the photoelectric conversion device can be used as a visible light sensor having favorable precision.

As shown in this embodiment, by making a taper shape in a portion where the electrode and the photoelectric conversion layer are in contact with each other, concentration of an electric field can be prevented. Further, step coverage of the photoelectric conversion layer in a portion where the electrode and the photoelectric conversion layer are in contact with each other is improved, and a concentration of a stress can be suppressed. Accordingly, characteristic deterioration can be reduced to improve reliability of the photoelectric conversion device.

It is to be noted that this embodiment can be combined with any description in Embodiment Mode.

### Embodiment 2

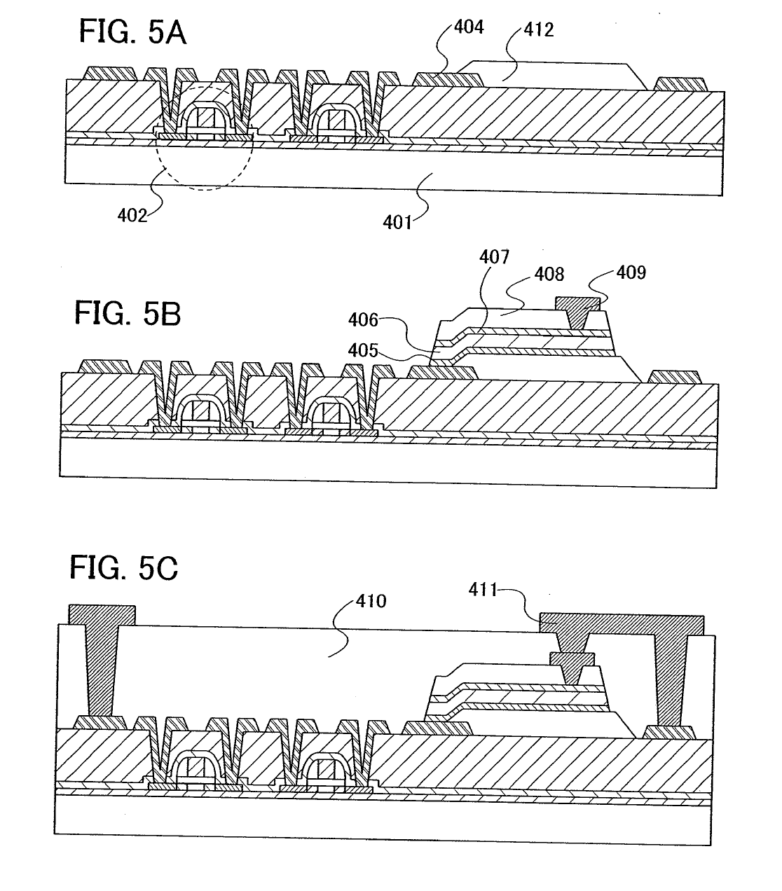

In this embodiment, in order to improve reliability of a photoelectric conversion device, an example of manufacturing a photoelectric conversion layer by protecting an edge portion of an electrode by a protective film after forming a thin film transistor will be explained with reference to FIGS. 4A to 4D, and FIGS. 5A to 5C. It is to be noted that the same portion with that in Embodiment 1 is denoted by the same reference numeral, and the photoelectric conversion layer may be manufactured based on the manufacturing step described in Embodiment 1.

In FIG. 4A, the electrode 403 is etched to form the electrode 404. At this time, a shape of an edge portion of the electrode 404 may not be a taper shape; however, by making the edge portion have a taper shape, coverage of a protective film 412 formed afterwards can be improved.

Next, the protective film 412 is formed from polyimide (refer to FIG. 5A). In this embodiment, the protective film is formed so as to transmit all light that enters in a photoelectric conversion layer formed afterwards. At this time, by using photosensitive polyimide, the protective film can be easily formed only by coating, light exposure, development, and baking. In addition, a taper becomes moderate, and coverage of a film manufactured in a subsequent step can be improved. In this case, a taper is formed to have an angle of equal to or less than 80 degrees, desirably equal to or less than 45 degrees. Further, this protective film may be formed using an insulating material such as acryl, siloxane, silicon oxide, or a material having high resistance, desirably, a material having higher resistance than that of a first semiconductor layer. In a case where light enters form the glass substrate 401 side, light has desirably high transmittance.

Here, before forming the first semiconductor layer in the subsequent step, baking, plasma treatment, or the like is desirably performed. Adsorption moisture of the protective film can be reduced, and adhesion thereof can be improved; therefore, reliability of the photoelectric conversion device is improved.

Subsequent steps are implemented similarly to Embodiment 1. FIG. 4C corresponds to FIG. 5B, and FIG. 4D corresponds to FIG. 5C.

As shown in this embodiment, the protective film is formed so as to reduce a step of the electrode, and the electrode and a photoelectric conversion layer are contacted with each other thereover, whereby concentration of an electric field can be prevented. Further, step coverage of the photoelectric conversion layer in a portion where the electrode and the photoelectric conversion layer are contacted with each other, and concentration of a stress can be suppressed. Accordingly, characteristic deterioration can be reduced to improve reliability of the photoelectric conversion device.

### Embodiment 3

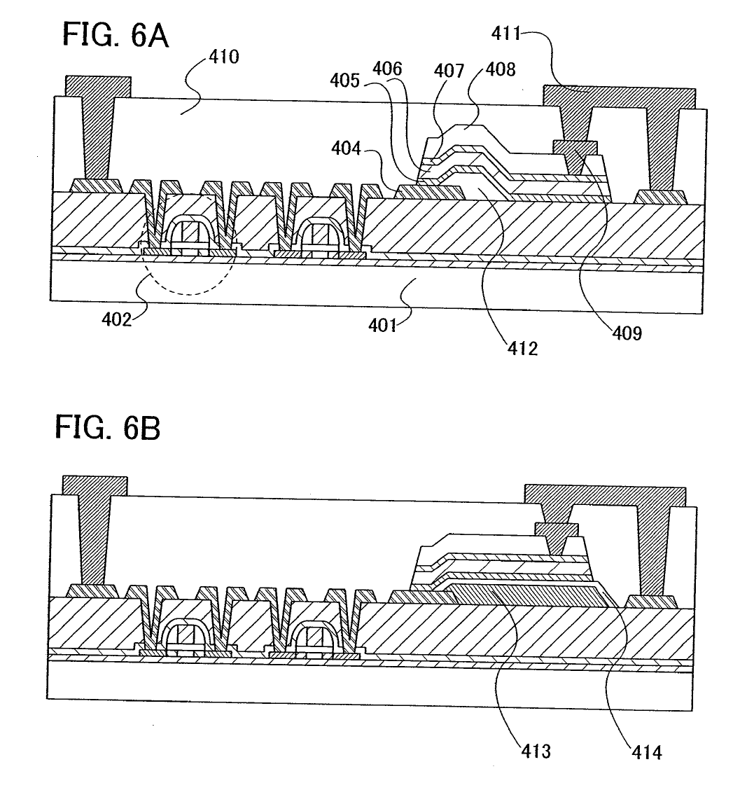

In this embodiment, in order to improve reliability of a photoelectric conversion device, in a case where a photoelectric conversion layer is manufactured by protecting an edge portion of an electrode by a protective film after forming a thin film transistor, an example of changing a pattern of the protective film will be explained with reference to FIG. 5C and FIG. 6A. It is to be noted that the same portion with that in Embodiment 2 is denoted by the same reference numeral, and the photoelectric conversion layer may be manufactured based on the manufacturing step described in Embodiment 2.

The protective film in FIG. 5C can be formed only on the periphery of the electrode 404 (refer to FIG. 6A).

By utilizing this embodiment, the photoelectric conversion layer can be used even when the protective film has no light transmitting property. In addition, light transmittance is increased, and then, efficiency of photoelectric conversion can be enhanced. Moreover, operation effect similar to that in Embodiment 2 can be obtained.

### Embodiment 4

In this embodiment, in a case where a photoelectric conversion layer is manufactured by protecting an edge portion of an electrode by a protective film after forming a thin film transistor in order to improve reliability of a photoelectric conversion device, an example of using a color filter for the protective film will be explained with reference to FIG. 5C and FIG. 6B. It is to be noted that the same portion with that in Embodiment 2 is denoted by the same reference numeral, and the photoelectric conversion layer may be manufactured based on the manufacturing step described in Embodiment 2.

The protective film 412 in FIG. 5C can be formed as a color filter 413 and an overcoat 414 (refer to FIG. 6B). The overcoat 414 is formed so as not to diffuse an impurity such as colorant contained in the color filter 413 to the photoelectric conversion layer. Further, by arranging the color filter in a portion that is extremely close to the photoelectric conversion layer in such a manner, light that enters from a horizontal direction can pass through the color filter; therefore, a photoelectric conversion device having high precision can be obtained.

Although not illustrated, color filters each of which a transmitting wavelength of light is different are formed by being coated with a different color in each photoelectric conversion element; accordingly, a photoelectric conversion device having different spectral sensitivity can be manufactured.

When a green color filter is used, visibility that is perceived by human and distribution of a wavelength that is transmitted into the photoelectric conversion layer are extremely close to each other; therefore, the photoelectric conversion device can be used as a visible light sensor having high precision. In addition, operation effect as similar to that in Embodiment 2 can be obtained.

### Embodiment 5

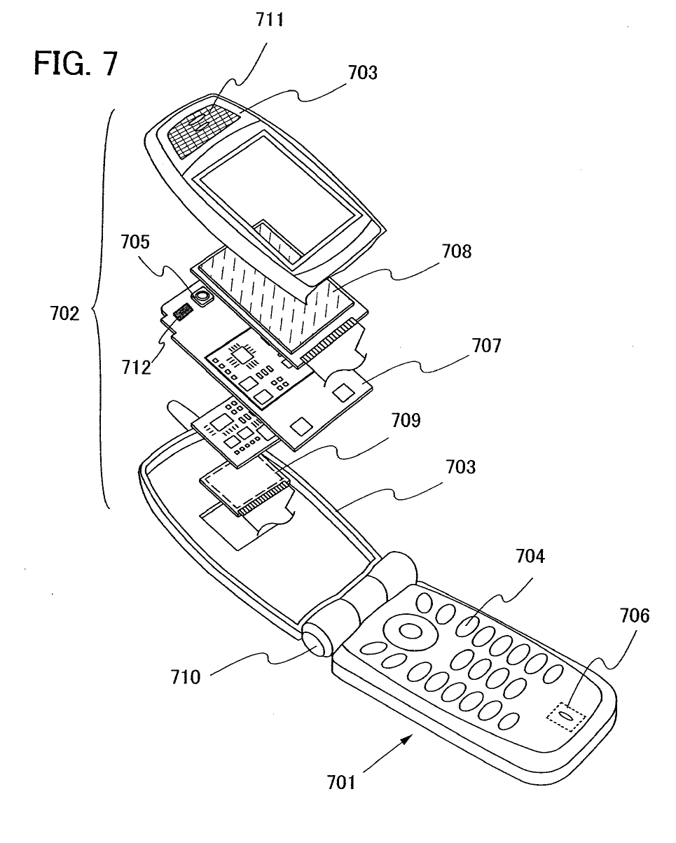

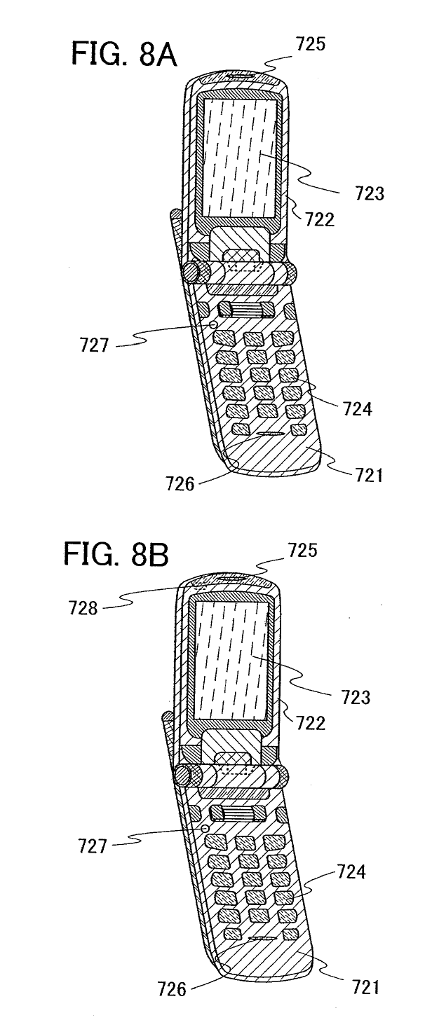

In this embodiment, an electronic device relating to the present invention is shown. As a specific example, a computer, a display, a cellular phone, a television, and the like can be given. These electronic devices will be explained with reference to FIG. 7, FIGS. 8A and 8B, FIGS. 9A and 9B, FIG. 10, and FIGS. 11A and 11B.

FIG. 7 shows a cellular phone, which includes a main body (A) 701, a main body (B) 702, a chassis 703, operation keys 704, an audio output potion 705, an audio input portion 706, a circuit board 707, a display panel (A) 708, a display panel (B) 709, a hinge 710, a light transmitting material portion 711, and a photoelectric conversion device 712 provided inside the chassis 703.

In the photoelectric conversion device 712, light transmitted from the light transmitting material portion 711 is detected, luminance control of the display panel (A) 708 and the display panel (B) 709 is performed corresponding to illuminance of the external light that is detected, and illuminance control of the operation keys 704 is performed corresponding to illuminance obtained in the photoelectric conversion device 712. Consequently, a consumption current of the cellular phone can be suppressed. This photoelectric conversion device 712 has the same structure as any one of structures shown in Embodiments 1 to 4; therefore, operation of the cellular phone can be stabilized.

FIGS. 8A and 8B show another example of a cellular phone. In both of FIG. 8A and FIG. 8B, a main body 721 includes a chassis 722, a display panel 723, operation keys 724, an audio output portion 725, an audio input portion 726, and a photoelectric conversion device 727.

In the cellular phone shown in FIG. 8A, external light is detected by the photoelectric conversion device 727 provided in the main body 721, whereby the luminance of the display panel 723 and the operation keys 724 can be controlled.

Further, the cellular phone shown in FIG. 8B, a photoelectric conversion device 728 in the main body 721 is provided in addition to the structure of FIG. 8A. The luminance of a backlight provided in the display panel 723 can be detected by the photoelectric conversion device 728.

In FIG. 7 and FIGS. 8A and 8B, the photoelectric conversion device provided with a circuit that amplifies a photoelectric current to be extracted as voltage output is provided in the cellular phone. Therefore, the number of components mounted on the circuit board can be reduced, and the cellular phone itself can be downsized. Further, the circuit and the photoelectric conversion device can be formed over the same substrate; therefore, noise can be reduced.

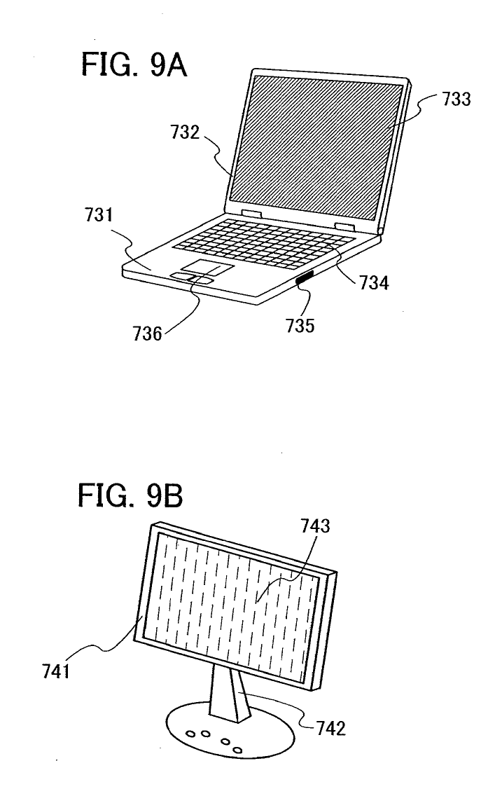

FIG. 9A shows a computer, which includes a main body 731, a chassis 732, a display portion 733, a keyboard 734, an external connecting port 735, a pointing mouse 736, and the like.

FIG. 9B is a display device corresponding to a television receiver or the like. This display device includes a chassis 741, a supporting base 742, a display portion 743, and the like.

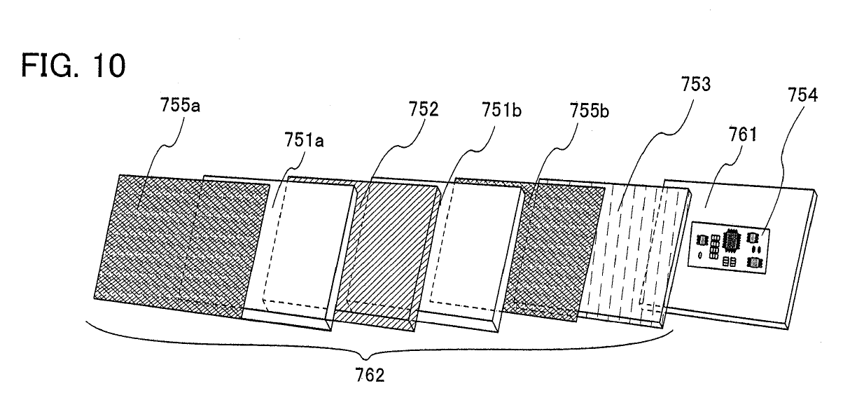

As the display portion 733 provided in the computer of FIG. 9A and the display portion 743 of the display device of FIG. 9B, a detailed structure in a case of using a liquid crystal panel is shown in FIG. 10.

A liquid crystal panel 762 shown in FIG. 10 is incorporated in a chassis 761, which includes substrates 751a and 751b, a liquid crystal layer 752 interposed between the substrates 751a and 751b, polarizing filters 755a and 755b, a backlight 753, and the like. Further, a photoelectric conversion device 754 is formed in the chassis 761.

The photoelectric conversion device 754 manufactured by using the present invention detects amount of light from the backlight 753, and the luminance of the liquid crystal panel 762 is adjusted by feedback of information of amount of light detection.

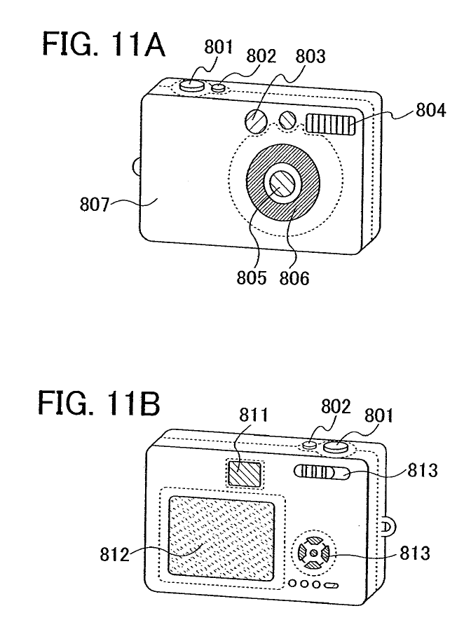

FIGS. 11A and 11B are views showing an example in which a light sensor of the present invention is incorporated into a camera such as a digital camera. FIG. 11A is a perspective view seen from a front side direction of the digital camera. FIG. 11B is a perspective view seen from a backside direction. In FIG. 11A, the digital camera is provided with a release button 801, a main switch 802, a viewfinder 803, a flash portion 804, a lens 805, a barrel 806, and a chassis 807.

In FIG. 11B, an eyepiece finder 811, a monitor 812, and operation buttons 813 are provided. When the release button 801 is pushed down to the half point, a focus adjustment mechanism and an exposure adjustment mechanism are operated, and when the release button is pushed down to the lowest point, a shutter is opened. By pushing down or rotating the main switch 802, a power supply of the digital camera is switched on or off.

The viewfinder 803 is located above the lens 805, which is on the front side of the digital camera, for checking a shooting range and the focus point from the eyepiece finder 811 shown in FIG. 11B. The flash portion 804 is located in the upper position on the front side of the digital camera. When the subject brightness is not enough, auxiliary light is emitted from the flash portion 804, at the same time as pushing down the release button to open a shutter. The lens 805 is located at the front side of the digital camera and made of a focusing lens, a zoom lens, and the like. The lens forms a photographic optical system with a shutter and a diaphragm that are not shown. In addition, behind the lens, an imaging device such as a CCD (Charge Coupled Device) is provided.

The barrel 806 moves a lens position to adjust the focus of the focusing lens, the zoom lens, and the like. In shooting, the barrel is slid out to move the lens 805 forward. Further, when carrying the digital camera, the lens 805 is moved backward to be compact. It is to be noted that a structure is employed in this embodiment, in which the subject can be photographed by zoom by sliding out the barrel; however, the present invention is not limited to this structure, and a structure may also be employed for the digital camera, in which shooting can be conducted by zoom without sliding out the barrel with the use of a structure of a photographic optical system inside the chassis 807.

The eyepiece finder 811 is located in the upper position on the backside of the digital camera for looking therethrough in checking a shooting range and the focus point. The operation buttons 813 are each a button for various functions provided on the backside of the digital camera, which includes a set up button, a menu button, a display button, a functional button, a selecting button, and the like.

When a light sensor of the present invention is incorporated in the camera shown in FIGS. 11A and 11B, the light sensor can detect whether light exists or not and light intensity; accordingly exposure adjustment of a camera or the like can be conducted. In addition, a light sensor of the present invention can also be applied to other electronic devices such as a projection TV and a navigation system. In other words, it can be applied to any object as long as it needs to detect light.

It is to be noted that this embodiment can be combined with any description in Embodiments 1 to 4.

### INDUSTRIAL APPLICABILITY

In accordance with the present invention, a coverage defect and concentration of an electric field of a photoelectric conversion layer are prevented in a connecting portion between the photoelectric conversion layer and an electrode, whereby deterioration can be suppressed. Further, by incorporating a photoelectric conversion device of the present invention, a highly reliable electronic device can be obtained.

This application is based on Japanese Patent Application serial no. 2005-334854 filed in Japan Patent Office on Nov. 18 in 2005, the entire contents of which are hereby incorporated by reference.

1. A photoelectric conversion device comprising:
a first electrode formed over a substrate;
a photoelectric conversion layer comprising a first semiconductor layer wherein the first semiconductor layer is formed on and in contact with the insulating film and a portion of the first electrode; and
a second electrode formed on and in contact with the photoelectric conversion layer,
wherein an edge portion of the first electrode has a tapered side surface.

2. The photoelectric conversion device according to claim 1, wherein a taper angle of the cross-section in the edge portion of the first electrode is equal to or less than 80 degrees.

3. The photoelectric conversion device according to claim 1, wherein an angle of a vertex in the cross-section of the first electrode in a portion being contacted with the first semiconductor layer is larger than 90 degrees.

4. The photoelectric conversion device according to claim 1, wherein the first electrode is connected to a transistor.

5. The photoelectric conversion device according to claim 4, wherein the transistor is a thin film transistor.

6. The photoelectric conversion device according to claim 1, wherein the substrate has selectivity of a light transmitting wavelength at least with respect to a wavelength in a range of visible light.

7. The photoelectric conversion device according to claim 1, further comprising;
a second semiconductor layer formed on the first semiconductor layer; and
a third semiconductor layer formed on the second semiconductor layer with a first conductivity type,
wherein the first semiconductor layer has a second conductivity type opposite to the first conductivity type.

8. An electronic device comprising the photoelectric conversion device according to claim 1, wherein the electronic device is one selected from the group consisting of a computer, a display device, a cellular phone, and a digital camera.

9. A photoelectric conversion device comprising:
a first electrode formed on an insulating surface;
a protective film formed on a portion of the insulating surface wherein the protective film covers an edge portion of the first electrode;
a photoelectric conversion layer comprising a first semiconductor layer wherein the first semiconductor layer is formed on and in contact with a portion of the first electrode and covers at least a portion of the protective film; and
a second electrode formed on and in contact with the photoelectric conversion layer,
wherein an edge portion of the protective film has a tapered side surface, and
wherein the edge portion of the protective film is overlapped with the edge portion of the first electrode at least partly.

10. The photoelectric conversion device according to claim 9, further comprising;
a second semiconductor layer formed on the first semiconductor layer; and
a third semiconductor layer formed on the second semiconductor layer with a first conductivity type,
wherein the first semiconductor layer has a second conductivity type opposite to the third conductivity type.

11. An electronic device comprising the photoelectric conversion device according to claim 9, wherein the electronic device is one selected from the group consisting of a computer, a display device, a cellular phone, and a digital camera.

12. A photoelectric conversion device comprising:
a first electrode formed on an insulating surface;
a protective film formed on a portion of the insulating surface wherein the protective film covers an edge portion of the first electrode;
a photoelectric conversion layer comprising a first semiconductor layer wherein the first semiconductor layer is formed on and in contact with a portion of the first electrode and covers a portion of the protective film; and
a second electrode formed on and in contact with the photoelectric conversion layer,
wherein an edge portion of the protective film has a tapered side surface, and
wherein the edge portion of the protective film is overlapped with the edge portion of the first electrode at least partly.

13. The photoelectric conversion device according to claim 12, wherein a cross-sectional shape in an edge portion of the first electrode in a portion being contacted with the protective film is a taper shape.

14. The photoelectric conversion device according to claim 13, wherein a taper angle of the cross-section in the edge portion of the first electrode is equal to or less than 80 degrees.

15. The photoelectric conversion device according to claim 12, wherein a taper angle of the cross-section in the edge portion of the protective film is equal to or less than 80 degrees.

16. The photoelectric conversion device according to claim 12, wherein an angle of a vertex in the cross-section of the protective film in a portion being contacted with the first semiconductor layer is larger than 90 degrees.

17. The photoelectric conversion device according to claim 12, wherein the protective film is insulating.

18. The photoelectric conversion device according to claim 12, wherein the protective film comprises a material having higher resistance than resistance of the first semiconductor layer.

19. The photoelectric conversion device according to claim 12, wherein the protective film comprises a light transmitting resin.

20. The photoelectric conversion device according to claim 12, wherein the protective film comprises a photosensitive material.

21. The photoelectric conversion device according to claim 12, wherein the first electrode is electrically connected to a transistor.

22. The photoelectric conversion device according to claim 21, wherein the transistor is a thin film transistor.

23. The photoelectric conversion device according to claim 12,
wherein the insulating surface is located over a substrate,
wherein the substrate has selectivity of a light transmitting wavelength at least with respect to a wavelength in a range of visible light.

24. The photoelectric conversion device according to claim 12, further comprising;
a second semiconductor layer formed on the first semiconductor layer; and
a third semiconductor layer formed on the second semiconductor layer with a first conductivity type,
wherein the first semiconductor layer has a second conductivity type opposite to the third conductivity type.

25. An electronic device comprising the photoelectric conversion device according to claim 12, wherein the electronic device is one selected from the group consisting of a computer, a display device, a cellular phone, and a digital camera.

26. A photoelectric conversion device comprising;
a first electrode formed on an insulating surface;
a protective film formed on a first portion of the insulating surface wherein the protective film covers an edge portion of the first electrode;
a photoelectric conversion layer comprising a first semiconductor layer wherein the first semiconductor layer is formed on and in contact with a portion of the first electrode and extends beyond the edge portion of the first electrode to cover the protective film and contact a second portion of the insulating surface,
wherein an edge portion of the protective film has a tapered side surface, and
wherein the edge portion of the protective film is overlapped with the edge portion of the first electrode at least partly.

27. The photoelectric conversion device according to claim 26, wherein a cross-sectional shape in an edge portion of the first electrode in a portion being contacted with the protective film is a taper shape.

28. The photoelectric conversion device according to claim 27, wherein a taper angle of the cross-section in the edge portion of the first electrode is equal to or less than 80 degrees.

29. The photoelectric conversion device according to claim 26, wherein a taper angle of the cross-section in the edge portion of the protective film is equal to or less than 80 degrees.

30. The photoelectric conversion device according to claim 26, wherein an angle of a vertex in the cross-section of the protective film in a portion being contacted with the first semiconductor layer is larger than 90 degrees.

31. The photoelectric conversion device according to claim 26, wherein the protective film is insulating.

32. The photoelectric conversion device according to claim 26, wherein the protective film comprises a material having higher resistance than resistance of the first semiconductor layer.

33. The photoelectric conversion device according to claim 26, wherein the protective film comprises a light transmitting resin.

34. The photoelectric conversion device according to claim 26, wherein the protective film comprises a photosensitive material.

35. The photoelectric conversion device according to claim 26, wherein the first electrode is electrically connected to a transistor.

36. The photoelectric conversion device according to claim 35, wherein the transistor is a thin film transistor.

37. The photoelectric conversion device according to claim 26,
wherein the insulating surface is located over a substrate,
wherein the substrate has selectivity of a light transmitting wavelength at least with respect to a wavelength in a range of visible light.

38. The photoelectric conversion device according to claim 26, further comprising;
a second semiconductor layer formed on the first semiconductor layer; and
a third semiconductor layer formed on the second semiconductor layer with a first conductivity type,
wherein the first semiconductor layer has a second conductivity type opposite to the third conductivity type.

39. An electronic device comprising the photoelectric conversion device according to claim 26, wherein the electronic device is one selected from the group consisting of a computer, a display device, a cellular phone, and a digital camera.

40. A photoelectric conversion device comprising:
a first electrode formed on an insulating surface;
a color filter formed on a portion of the insulating surface wherein the color filter covers an edge portion of the first electrode;
a photoelectric conversion layer comprising a first semiconductor layer wherein the first semiconductor layer is formed on and in contact with a portion of the first electrode and covers a portion of the color filter; and
a second electrode formed on and in contact with the photoelectric conversion layer.

41. The photoelectric conversion device according to claim 40, wherein a cross-sectional shape in an edge portion of the first electrode in a portion being contacted with the color filter is a taper shape.

42. The photoelectric conversion device according to claim 41, wherein a taper angle of the cross-section in the edge portion of the first electrode is equal to or less than 80 degrees.

43. The photoelectric conversion device according to claim 40, wherein an edge portion of the protective film has a tapered side surface.

44. The photoelectric conversion device according to claim 43, wherein a taper angle of the cross-section in the edge portion of the color filter is equal to or less than 80 degrees.

45. The photoelectric conversion device according to claim 40, wherein an angle of a vertex in the cross-section of the color filter in a portion being contacted with the first semiconductor layer is larger than 90 degrees.

46. The photoelectric conversion device according to claim 40, wherein the first electrode is connected to a transistor.

47. The photoelectric conversion device according to claim 46, wherein the transistor is a thin film transistor.

48. The photoelectric conversion device according to claim 40,
wherein the insulating surface is located over a substrate, and
wherein the substrate has selectivity of a light transmitting wavelength at least with respect to a wavelength in a range of visible light.

49. The photoelectric conversion device according to claim 40, further comprising;
a second semiconductor layer formed on the first semiconductor layer; and
a third semiconductor layer formed on the second semiconductor layer with a first conductivity type,
wherein the first semiconductor layer has a second conductivity type opposite to the third conductivity type.

50. An electronic device comprising the photoelectric conversion device according to claim 40, wherein the electronic device is one selected from the group consisting of a computer, a display device, a cellular phone, and a digital camera.
